(19) United States
(12) Patent Application Publication
(10) Pub. No.: US 2007/0135067 A1
(43) Pub. Date: Jun. 14, 2007

(54) Apparatus for configuring portable communication system using multipath power amplifier

(75) Inventor: Kyoung-Tae Kim, Yongin-si (KR)

Correspondence Address: THE FARRELL LAW FIRM, P.C., 333 EARLE OVINGTON BOULEVARD, SUITE 701, UNIONDALE, NY, 11553, US

(73) Assignee: Samsung Electronics Co., Ltd., Suwon-si (KR)

(21) Appl. No.: 11/638,073

(22) Filed: Dec. 13, 2006

(30) Foreign Application Priority Data
Dec. 13, 2005 (KR) 2005-0122406

(51) Int. Cl. H01Q 11/12; H03G 3/20; H03F 3/68

(52) U.S. Cl. 455/127.3; 330/136; 330/124 R

(57) ABSTRACT

Disclosed is an apparatus for configuring a portable communication system using a multipath amplifier that includes dividers for respective sectors which divide an input signal of a corresponding sector and provide the divided input signals to an internal amplifier for the corresponding sector of a certain number of multipath power amplifiers. The multipath power amplifiers, which include internal amplifiers for the respective sectors, amplify and output input signals for sectors fed from the internal amplifiers for the respective sectors. Combiners are provided for respective sectors which combine the amplified signals fed from the internal amplifiers for the corresponding sector of the certain number of the multipath power amplifiers and output the combined signal to an antenna of the corresponding sector.

### PRIORITY

This application claims priority under 35 U.S.C. § 119 to an application filed in the Korean Intellectual Property Office on Dec. 13, 2005 and assigned Serial No. 2005-122406, the contents of which are incorporated herein by reference.

### BACKGROUND OF THE INVENTION

1. Field of the Invention

The present invention relates generally to a portable communication system, and, in particular, to an apparatus for configuring a portable communication system using a multipath power amplifier.

2. Description of the Related Art

The related art has configured a portable communication base station using a single-path amplifier. A high-power amplifier used for the portable communication base station has adopted a duplication method to prevent service interruption during operation. Generally, the duplication method includes a method of changing a path by a high frequency switch. The base station is generally used as an omni-directional system which provides services in all directions over a single antenna and as a sector system configured with a plurality of sector antennas.

FIGS. 1A-C depict an omni-directional system using a single-path amplifier and a duplicate configuration of the related art. Referring to FIGS. 1A-C, the omni-directional system, in which a single antenna 102 transmits and receives signals in all directions, can include an amplifier 110 or combination of a plurality of amplifiers 103-1 through 103-N. Configured with the plurality of the amplifiers 103-1 through 103-N, the omni-directional system shown in FIG. 1B divides an incoming signal at a divider 104, amplifies the divided signals at the amplifiers 103-1 through 103-N, respectively, combines the amplified signals at a combiner 105, and then outputs one signal to the antenna 102. The omni-directional system shown in FIG. 1B can be used when a capacity increase is necessary due to an increased number of users. If the amplifier suffers error, the cell radius shrinks but service is not interrupted. Hence, the duplication method is not applied in most cases.

As for the omni-directional system shown in FIG. 1A that is configured with one amplifier 101, error of the amplifier 101 can cause service interruption. The service interruption because of the amplifier error can be avoided by employing the duplication method which configures a system using a duplicate amplifier in addition to the single amplifier. The system shown in FIG. 1C, which further includes a duplicate amplifier 107 in addition to the amplifier 106, is able to carry out the duplication in various methods using high frequency switches 108 and 109. Specifically, when there an error does not exist at the amplifier 106, the incoming signal is amplified and fed to the amplifier 106. When an error exists at the amplifier 106, the service interruption can be avoided by switching the signal to the duplicate amplifier 107 utilizing the high frequency switches 108 and 109 that are connected to input ports and output ports of the amplifiers 106 and 107. At this time, two amplifiers can be combined in an alternative method, but the efficiency of the power consumption will degrade because the two amplifiers produce the output at the same time.

FIGS. 2A-C depict a sector system configuration using a single-path amplifier and a duplicate configuration of the related art. Herein, a 3-sector system is utilized as an example for this explanation.

Referring to FIGS. 2A-C, the sector system, which transmits and receives signals in all directions via a plurality of sector antennas 204, 205, and 206, can include amplifiers 201, 202, and 203 or combinations of a plurality of amplifiers 207-1 through 207-N, 208-1 through 208-N, and 209-1 through 209-N for the respective sectors.

The sector system shown in FIG. 2B, which is configured with combinations of amplifiers 207-1 through 207-N, 208-1 through 208-N, and 209-1 through 209-N for the respective sectors, divides incoming signals for sectors at dividers 210, 211, and 212, respectively, amplifies the divided signals for the sectors at the amplifiers 207-1 through 207-N, 208-1 through 208-N, and 209-1 through 209-N, combines the amplified signals at combiners 213, 214, and 215, and outputs the combined signals to antennas 204, 205, and 206 for the sectors. The sector system shown in FIG. 2B can be used where capacity increase is needed due to an increased number of users. Generally, however, the duplication method is not applied because service interruption does not occur even when an error happens at one amplifier.

In the sector system shown in FIG. 2A configured with the amplifiers 201, 202, and 203 for the respective sectors, error of amplifier 201, 202, or 203 results in service interruption of the corresponding sector. Thus, the duplication method is applied by using a duplicate amplifier in addition to the amplifiers so as to avoid the service interruption because of amplifier error. For this example, the duplicate structure shown in FIG. 2C of the 3-sector system includes four amplifiers in total, that is, amplifiers 216, 217, and 218 for respective sectors and a duplicate amplifier 219, and 4:4 switches 220 and 221 disposed at input and output ports of the amplifiers 216, 217, 218, and 219. When an error does not occur at any of amplifier 216, 217, and 218 for the sectors, incoming signals of the corresponding sectors are amplified at the amplifiers 216, 217 and 218 for sectors and output to antennas 204, 205, and 206 of the corresponding sectors. When there is an error at one of the amplifiers 216, 217, and 218 for the sectors, the signal fed to that amplifier is switched to the duplicate amplifier 219 using the 4:4 switches 220 and 221, thus blocking the service interruption.

As such, the conventional duplicate structure is applicable to the single-path amplifier. For a multipath power amplifier having several paths in the same amplifier, the system configuration and the duplication method are altered. Therefore, a demand exists for a duplicate structure applicable to the multipath power amplifier.

### SUMMARY OF THE INVENTION

An aspect of the present invention is to substantially solve at least the above problems and/or disadvantages and to provide at least the advantages below. Accordingly, an aspect of the present invention is to provide an apparatus for configuring a portable communication system using a multipath power amplifier.

Another aspect of the present invention is to provide a system structure and a duplicate structure, to which a multipath power amplifier and a multipath switching combiner are applied.

The above aspects are achieved by providing an apparatus for configuring a portable communication system which distinguishes sectors using a multipath power amplifier, which includes dividers for respective sectors which divide an input signal of a corresponding sector and provide the divided input signals to an internal amplifier for the corresponding sector of a certain number of multipath power amplifiers; the multipath power amplifiers which include internal amplifiers for the respective sectors, amplify and output input signals for sectors fed from the internal amplifiers for the respective sectors; and combiners for respective sectors which combine the amplified signals fed from the internal amplifiers for the corresponding sector of the certain number of the multipath power amplifiers and output the combined signal to an antenna of the corresponding sector.

According to one aspect of the present invention, an apparatus for configuring a portable communication system which distinguishes sectors using a multipath power amplifier, includes a first N:N switch which switches input signals for respective sectors to amplifiers for respective sectors in a first multipath power amplifier by connecting output ports of an internal switch to an input port of an amplifier for the sector in the first multipath power amplifier and to an input port of one amplifier in a second multipath power amplifier, and switches an input signal for a sector to the one amplifier in the second multipath power amplifier when error occurs at one amplifier of the internal amplifiers for the respective sectors; the first multipath power amplifier which includes the internal amplifier for the respective sectors, amplifies and outputs input signals for the sectors fed to the internal amplifiers for the respective sectors; the second multipath power amplifier which includes at least one internal amplifier, amplifies and outputs an input signal fed to the internal amplifier; and a second N:N switch which switches the amplified signals fed from the amplifiers for the sectors of the first multipath power amplifier by connecting input ports of an internal switch to an output port of one of the amplifiers for the sectors of the first multipath power amplifier and to an output port of one of the internal amplifiers of the second multipath power amplifier, and switches the amplified signal fed from one of the internal amplifiers of the second multipath power amplifier when error occurs at the one amplifier of the internal amplifiers for the sectors.

According to another aspect of the present invention, an apparatus for configuring a portable communications system which distinguishes sectors using a multipath power amplifier, includes first N:N multipath switching combiners for respective sectors which switch an input signal for a specific sector to an amplifier of a corresponding sector in a first multipath power amplifier by connecting output ports of an internal switch to input ports of amplifiers of the corresponding sector in the first multipath power amplifier and a second multipath power amplifier, and switch the input signal to the amplifier for the corresponding sector in the second multipath power amplifier when error occurs at the amplifier for the corresponding sector of the first multipath power amplifier; the first and second multipath power amplifiers which include internal amplifiers for the respective sectors, amplify and output input signals for the sectors fed to the internal amplifiers for the respective sectors; and second N:N multipath switching combiners which switch the amplified signal fed from the amplifier for the corresponding sector of the first multipath power amplifier to an antenna of the corresponding sector by connecting input ports of an internal switch to output ports of the amplifiers for the corresponding sector of the first and second multipath power amplifiers, and switch the amplified signal fed from the amplifier for the corresponding sector in the second multipath power amplifier to an antenna of the corresponding sector when error occurs at the amplifier for the corresponding sector of the first multipath power amplifier.

### BRIEF DESCRIPTION OF THE DRAWINGS

The above and other objects, features and advantages of the present invention will become more apparent from the following detailed description when taken in conjunction with the accompanying drawings in which:

FIGS. 1A-C depict an omni-directional system configuration using a single-path amplifier and a duplicate structure of the related art;

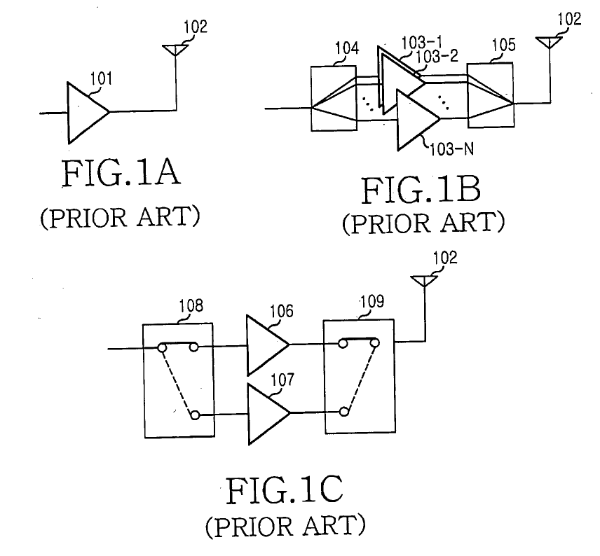

FIGS. 2A-C depict a sector system configuration using a single-path amplifier and a duplicate structure of the related art;

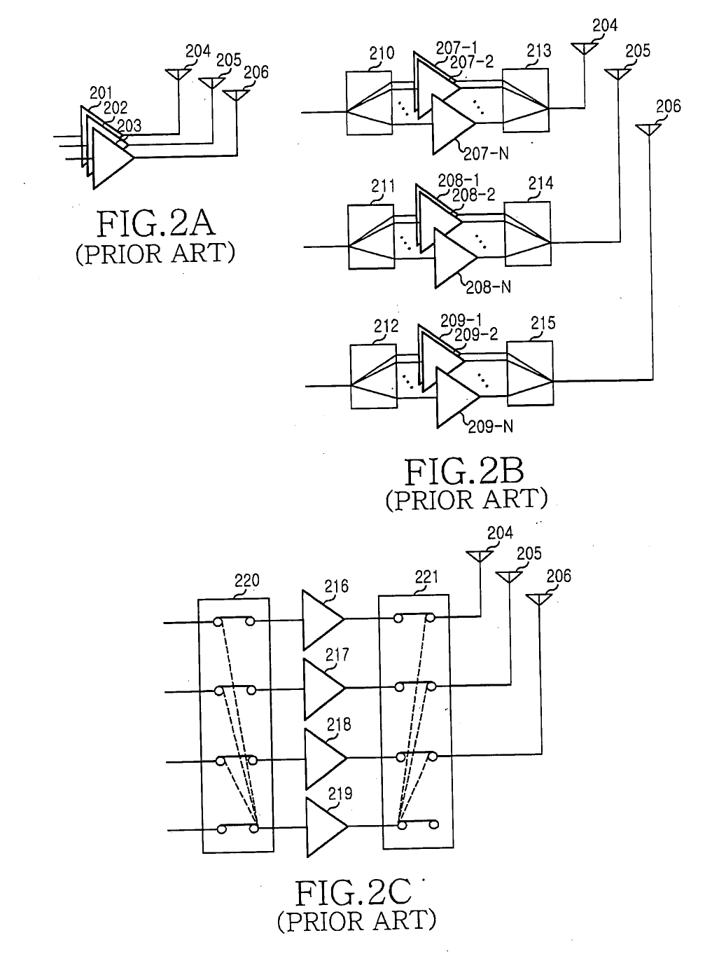

FIGS. 3A-C illustrate an omni-directional system using a multipath power amplifier and a duplicate structure according to the present invention;

FIGS. 4A-C illustrate structure and operation of a multipath switching combiner according to the present invention;

FIGS. 5A and 5B illustrate a sector system configuration using a multipath power amplifier according to the present invention; and

FIGS. 6A and 6B illustrate a duplicate structure of the sector system using the multipath power amplifier according to the present invention.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

The present invention provides an apparatus for configuring a portable communication system using a multipath power amplifier. Herein, the multipath power amplifier, which includes N-ary internal amplifiers, has N-ary internal paths, N-ary input ports, and N-ary output ports.

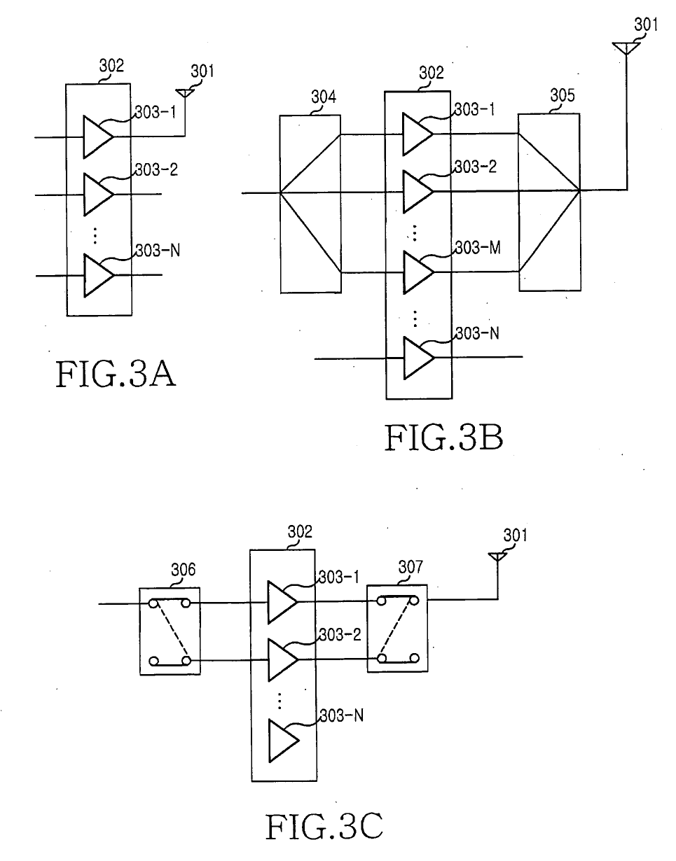

FIGS. 3A-C illustrate an omni-directional system using a multipath power amplifier and a duplicate structure according to the present invention. Referring to FIG. 3A, the omni-directional system using the multipath power amplifier includes a multipath power amplifier 302, which includes N-ary internal amplifiers 303-1 through 303-N and supports their paths for N-ary inputs, and an antenna 301.

Where service is provided using only one of the N-ary internal paths due to a small number of initial users, the omni-directional system shown in FIG. 3A can be configured merely using one amplifier 303-1 amongst the amplifiers 303-1 through 303-N integrated in the multipath power amplifier 302. In this case, when a signal is input through the input port connected to the amplifier 303-1, the amplifier 303-1 amplifies the input signal and outputs the amplified signal to the antenna 301 through its output port.

Where capacity of the amplifier needs to increase due to an increased number of users, the omni-directional system shown in FIG. 3B can provide services using M-ary internal paths of the N-ary internal paths. In this case, the omni-directional system shown in FIG. 3B can be configured with M-ary amplifiers 303-2 through 303-M of the amplifiers 303-1 through 303-N integrated in the multipath power amplifier 302, a divider 304 which divides an incoming signal to M-ary signals and outputs the M-ary signals to input ports connected to the M-ary amplifiers 303-2 through 303-M, and a combiner 305 which combines signals from output ports connected to the M-ary amplifiers 303-2 through 303-M to one signal and outputs the one signal to the antenna 301. That is, a greater number of users can be serviced by combining the other internal paths in addition to the existing internal path.

As shown in FIG, 3B, the divider 304 divides the input signal and transfers the divided signals to a certain number of amplifiers 303-1 through 303-M of the amplifiers 303-1 through 303-N integrated in the multipath power amplifier 302. When the certain number of the amplifiers 303-1 through 303-M of the multipath power amplifier 302 amplify the divided signals and send the amplified signals to the combiner 305, the combiner 305 combines the amplified signals and outputs the combined signal over the antenna 301, to thereby increase the service volume for the corresponding path. Note that the divider 304 and the combiner 305 can incorporate a certain number of amplifiers for their capacities without structural modification utilizing a multipath switching combiner

The duplicate structure shown in FIG. 3C of the omni-directional system shown in FIG. 3A services only one internal path using only one amplifier 303-1 amongst amplifiers 303-1 through 303-N integrated in the multipath power amplifier 302. The duplicate structure shown in FIG. 3C is configured using a first N:N multipath switching combiner 306 which utilizes another amplifier, other than amplifier 303-1, of the amplifiers 303-2 through 303-N integrated in the multipath power amplifier 302 as a duplicate amplifier 303-2 and, in this example, switches an input signal between input ports of amplifiers 303-1 and 303-2, and a second N:N multipath switching combiner 307 which outputs a signal from an output port of one of the amplifiers 303-1 and 303-2 to the antenna 301. In doing so, when an error does not exist at amplifier 303-1, the input signal is switched to the amplifier 303-1 by means of the 2:2 multipath switching combiners 306 and 307, respectively connected to the input ports and the output ports of the amplifiers 303-1 and 303-2. When the amplifier 303-1 suffers an error, the input signal is switched to the duplicate amplifier 303-2 through the 2:2 multipath switching combiners 306 and 307, respectively connected to the input ports and the output ports of the amplifiers 303-1 and 303-2. Thus, service interruption due to the amplifier error can be avoided.

In further detail, the first N:N multipath switching combiner 306 switches the input signal to one internal amplifier 303-1 of the multipath power amplifier 302. When error occurs at the internal amplifier 303-1, the first N:N multipath switching combiner 306 switches the input signal to another internal amplifier 303-2 of the multipath power amplifier 302. The second N:N multipath switching combiner 307 switches the signal fed from the internal amplifier 303-1 of the multipath power amplifier 302 to the antenna 301. When error occurs at the internal amplifier 303-1, the second N:N multipath switching combiner 307 switches to the another internal amplifier 302-2 and transfers the signal fed from the amplifier 302-2 to the antenna 301.

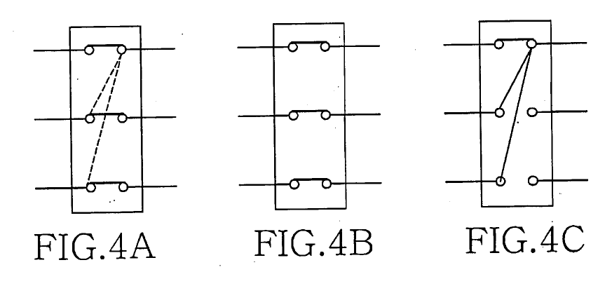

Referring now to FIGS. 4A-C, structures and operations of the multipath switching combiners 306 and 307 are explained. The multipath switching combiner shown in FIG. 4A includes N-ary switches for supporting the multipath with N-ary inputs and N-ary outputs. The multipath switching combiner shown in FIG. 4A can achieve various implementations such as the function shown in FIG. 4B of simply connecting the multipath and the function shown in FIG. 4C of combining multiple paths. In addition, the multipath switching combiner shown in FIG. 4A can implement a function of dividing one path to multiple paths.

As such, when the omni-directional system is configured using the multipath power amplifier and the multipath switching combiner, an increase in duplication and system capacity can be accomplished without an additional amplifier of switch.

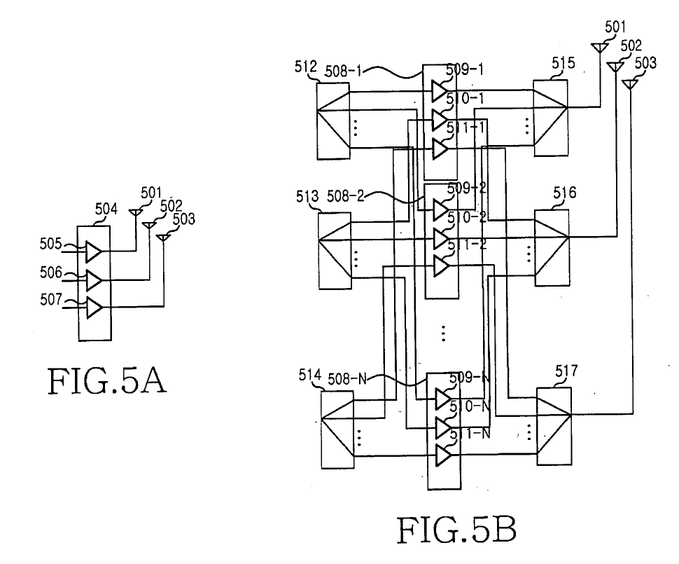

FIGS. 5A and 5B illustrate a sector system configuration using a multipath power amplifier according to the present invention. In FIGS. 5A and 5B, a 3-sector system is utilized as an example for explaining the sector system.

Referring to FIGS. 5A and 5B, for service using only one internal path per sector for a small number of initial users, the sector system shown in FIG. 5A transmitting signals to a plurality of sector antennas 501, 502, and 503 includes amplifiers 505, 506, and 507 for the respective sectors. The amplifiers 505, 506, and 507 support their respective paths. The amplifiers 505, 506, and 507 can be integrated into one multipath power amplifier 504. In this case, when input signals for the respective sectors are fed to input ports connected to the internal amplifiers 505, 506, and 507, the internal amplifiers 505, 506, and 507 amplify the input signals and output the amplified signals to antennas 501, 502, and 503 of the corresponding sectors through their output ports.

When increasing the capacity of the amplifiers for the respective sectors because of an increased number of the users, the sector system shown in FIG. 5B includes a certain number of multipath power amplifiers 508-1 through 508-N in proportion to the capacity increase, dividers 512, 513, and 514 for the respective sectors, and combiners 515, 516, and 517. A number of amplifiers corresponding to the number of the sectors are integrated in each of the multipath power amplifiers 508-1 through 508-N. Among the amplifiers 509-1 through 511-1, 509-2 through 511-2, and 509-N through 511-N integrated in the respective multipath power amplifiers 508-1 through 508-N, amplifiers 509-1 through 509-N are responsible to increase the amplifier capacity with respect to the first sector, amplifiers 510-1 through 510-N are responsible to increase the amplifier capacity with respect to the second sector, and the other amplifiers 509-N through 511-N are responsible to increase the amplifier capacity with respect to the third and subsequent sectors.

The first divider 512 for the first sector divides an incoming signal to signals corresponding in number to the number of multipath power amplifiers and outputs the divided signals to the input ports of amplifiers 509-1 through 509-N for the corresponding sector. The first combiner 515 combines the input signals for the first sector, which are amplified at the amplifiers 509-1 through 509-N, and outputs the combined signal to a first antenna 501.

The second divider 513 for the second sector divides an incoming signal to signals corresponding in number to the number of multipath power amplifiers and outputs the divided signals to the input ports of the amplifiers 510-1 through 510-N for the corresponding sector. The second combiner 516 combines the input signals for the second sector, which are amplified at the amplifiers 510-1 through 510-N, and outputs the combined signal to a second antenna 502.

The third divider 514 for the third sector divides an incoming signal to signals corresponding in number to the number of the multipath power amplifiers and outputs the divided signals to the input ports of the amplifiers 511-1 through 511-N for the corresponding sector. The third combiner 517 combines the input signals for the third sector, which are amplified at the amplifiers 511-1 through 511-N and outputs the combined signal to a third antenna 503.

As a result, a greater number of users can be serviced for the respective sectors. Note that the dividers 512, 513, and 514 and the combiners 515, 516, and 517 can employ a multipath switching combiner.

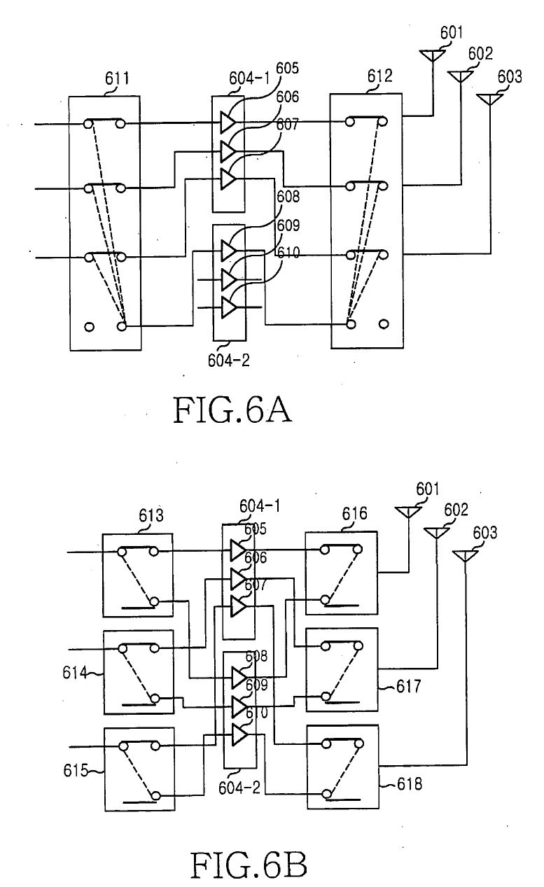

FIGS. 6A and 6B illustrate a duplicate structure of the sector system using the multipath power amplifier according to the present invention. Herein, a 3-sector system is utilized as an example to explain the sector system.

Referring to FIGS. 6A and 6B, the duplication of the multipath power amplifier can be achieved using an N:N switch in one way or using a multipath switching combiner in another way. The sector system which transmits and receives signals via a plurality of sector antennas 601, 602, and 603, includes amplifiers 605, 606, and 607 for the respective sectors. The amplifiers 605, 606, and 607 for the respective sectors support their respective paths. The amplifiers 605, 606, and 607 can be integrated in a first multipath power amplifier 604-1. For the duplicate structure of the sector system, a second multipath power amplifier 604-2 can be further provided. A certain number of amplifiers 608, 609, and 610 can be integrated in the second multipath power amplifier 604-2.

The duplicate structure shown in FIG. 6A of the multipath power amplifier using the N:N switch further includes a pair of N:N switches having at least one or more input and output ports when the input and output ports of the first multipath power amplifier 604-1. The output ports of the first N:N switch 611 are connected to the respective input ports of the internal amplifier 605, 606, and 607 of the first multipath power amplifier 604-1, and the input ports of the second N:N switch 612 are connected to the respective output ports of the internal amplifiers 605, 606, and 607. The first N:N switch 611 switches the input signals for the sectors to the corresponding amplifiers 605, 606, and 607 for the sectors of the first multipath power amplifier 604-1. The second N:N switch 612 switches the signals amplified at the amplifiers 605, 606, and 607 for the sectors, to the corresponding antennas 601, 602 and 603 for the sectors. The output port of one of the switches in the first N:N switch 611 is connected to the input port of one amplifier 608 integrated in the second multipath power amplifier 604-2. Likewise, the output port of the amplifier 608 can be connected to the input port of one of the switches in the second N:N switch 612. Accordingly, if an error occurs at one of the amplifiers 605, 606, and 607 for the sectors, the corresponding amplifier can be substituted by the amplifier 608 integrated in the second multipath power amplifier 604-2.

For this example, when an error occurs at the amplifier 608 for the first sector, a signal for the first sector can be transferred to the first antenna 601 via the amplifier 608 integrated in the second multipath power amplifier 604-2. At this time, to establish the connection path for the first sector, the first N:N switch 611 and the second N:N switch 612 switch to the amplifier 608 of the second multipath power amplifier 604-2, rather than to the erroneous amplifier 605. As such, when the duplication is implemented using the N:N switches, and better efficiency is provided.

Alternatively, the duplicate structure shown in FIG. 6B of the multipath power amplifier using the multipath switching combiner further includes a pair of N:N multipath switching combiners for the respective sectors. Amplifiers 608, 609, and 610 integrated in a second multipath power amplifier 604-2 connected for the duplicate structure, are amplifiers for the respective sectors to support the respective duplicate paths. Herein, “N” equals the number of the multipath power amplifiers.

According to the present invention, a 2:2 multipath switching combiner is provided as an example. As for the first sector, the output ports of the first multipath switching combiner 613 are connected to the input ports of the internal amplifiers 605 and 608 for the corresponding sector in the first multipath power amplifier 604-1 and the second multipath power amplifier 604-2. The output ports of the internal amplifiers 605 and 608 are connected to the input ports of the second multipath switching combiner 616.

As for the second sector, the output ports of the third multipath switching combiner 614 are connected to the input ports of the internal amplifiers 606 and 609 for the corresponding sector in the first multipath power amplifier 604-1 and the second multipath power amplifier 604-2. The output ports of the internal amplifiers 606 and 609 are connected to the input ports of the fourth multipath switching combiner 617.

As for the third sector, the output ports of the fifth multipath switching combiner 615 are connected to the input ports of the internal amplifiers 607 and 610 for the corresponding sector in the first multipath power amplifier 604-1 and the second multipath power amplifier 604-2. The output ports of the internal amplifiers 607 and 610 are connected to the input ports of the sixth multipath switching combiner 618. If an error does not occur at the amplifiers 605, 606, and 607 for the respective sectors of the first multipath power amplifier 604-1, the first multipath switching combiner 613 switches the signal for the first sector to the corresponding internal amplifier 605 of the first multipath power amplifier 604-1. The internal amplifier 605 amplifies and outputs the input signal, and the second multipath switching combiner 616 switches the amplified signal to the antenna 601 of the corresponding sector. The third multipath switching combiner 614 switches a signal for the second sector to the corresponding internal amplifier 606 of the first multipath power amplifier 604-1, the internal amplifier 606 amplifies and outputs the input signal, and the fourth multipath switching combiner 617 switches the amplified signal to the antenna 602 of the corresponding sector.

The fifth multipath switching combiner 615 switches a signal for the third sector to the corresponding internal amplifier 607 of the first multipath power amplifier 604-1, the internal amplifier 607 amplifies and outputs the input signal, and the sixth multipath switching combiner 618 switches the amplified signal to the antenna 603 of the corresponding sector. By contrast, when an error occurs at amplifiers 605, 606, and 607 of the first multipath power amplifier 604-1, the multipath switching combiner of the corresponding sector switches an incoming signal to the corresponding internal amplifier of the second multipath power amplifier 604-2. Next, the corresponding internal amplifier amplifies and outputs the input signal, and another multipath switching combiner for the corresponding sector switches the amplified signal to the antenna of the corresponding sector. As a result, it is possible to support the duplicate path for the corresponding sector. When implementing the duplication using the multipath switching combiner as described above, the present invention can increase the system capacity merely adding the amplifier without additional modification.

As set forth above, the present invention provides a system with duplicate structure by employing the multipath power amplifier and the multipath switching combiner in the portable communication system. Decreasing the size and the cost of the system and adopting the above-described duplication method, system stabilization and system expansion are simultaneously achieved and competitive system characteristics realized.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus for configuring a portable communication system which distinguishes sectors using a multipath power amplifier, comprising:
dividers for respective sectors that divide an input signal of a corresponding sector and provide the divided input signals to an internal amplifier for the corresponding sector of one of a plurality of multipath power amplifiers,
wherein the multipath power amplifiers include internal amplifiers for the respective sectors, amplify and output input signals for sectors fed from the internal amplifiers for the respective sectors; and
combiners for respective sectors which combine the amplified signals fed from the internal amplifiers for the corresponding sector of a plurality of the multipath power amplifiers and output the combined signal to an antenna of the corresponding sector.

2. The apparatus of claim 1, wherein three sectors comprise the corresponding sectors.

3. The apparatus of claim 1, further comprising:
a plurality of antennas each corresponding to a respective sector that transmit signals fed from the combiners for the respective sectors.

4. An apparatus for configuring a portable communication system which distinguishes sectors using a multipath power amplifier, comprising;
a first N:N switch which switches input signals for respective sectors to amplifiers for respective sectors in a first multipath power amplifier by connecting output ports of an internal switch to an input port of an amplifier for a sector in the first multipath power amplifier and to an input port of one amplifier in a second multipath power amplifier, and switches an input signal for the sector to the one amplifier in the second multipath power amplifier when an amplifier error occurs for the respective sector,
wherein the first multipath power amplifier includes an internal amplifier for respective sectors, and amplifies and outputs the input signals for the sectors fed to internal amplifiers for respective sectors, and
the second multipath power amplifier includes at least one internal amplifier, and amplifies and outputs an input signal fed to the internal amplifier; and
a second N:N switch which switches the amplified signals fed from the amplifiers for the sectors of the first multipath power amplifier by connecting input ports of an internal switch to an output port of one of the amplifiers for the sectors of the first multipath power amplifier and to an output port of one of the internal amplifiers of the second multipath power amplifier, and switches the amplified signal fed from one of the internal amplifiers of the second multipath power amplifier when the amplifier error occurs.

5. The apparatus of claim 4, wherein N is greater than a number of the sectors by at least one.

6. The apparatus of claim 4, wherein the number of sectors is three.

7. An apparatus for configuring a portable communications system which distinguishes sectors using a multipath power amplifier, comprising:
first N:N multipath switching combiners for respective sectors which switch an input signal for a specific sector to an amplifier of a corresponding sector in a first multipath power amplifier by connecting output ports of an internal switch to input ports of amplifiers of the corresponding sector in the first multipath power amplifier and a second multipath power amplifier, and switch the input signal to the amplifier for the corresponding sector in the second multipath power amplifier when an error occurs at the first multipath power amplifier,
wherein the first and second multipath power amplifiers include internal amplifiers for the respective sectors, and amplify and output input signals for the sectors fed to the internal amplifiers for the respective sectors; and
second N:N multipath switching combiners which switch the amplified signal fed from the amplifier for the corresponding sector of the first multipath power amplifier to an antenna of the corresponding sector by connecting input ports of an internal switch to output ports of amplifiers for the corresponding sector of the first and second multipath power amplifiers, and switch the amplified signal fed from the amplifier for the corresponding sector in the second multipath power amplifier to the antenna of the corresponding sector when the error occurs at the first multipath power amplifier.

8. The apparatus of claim 7, wherein N equals a number of the multipath power amplifiers.

9. The apparatus of claim 7, wherein a number of sectors is three.

10. A communication system using a multipath power amplifier, comprising:
at least one multipath power amplifier including internal amplifiers wherein each of the internal amplifiers amplify each corresponding input signals; and
at least one combiner for combining the amplified signals from the internal amplifiers of the corresponding multipath power amplifier.

11. The system of claim 10, further comprising:
at least one antenna for transmitting the combined signal from the combiner.

12. The system of claim 11, wherein each number of multipath power amplifier, combiner and antenna are three.

13. The system of claim 10, further comprising:
at least one divider for dividing an input signal and providing the divided input signals to each internal amplifier of the multipath power amplifier.

14. A communication system using a multipath power amplifier, comprising:
at least one multipath power amplifier including internal amplifiers wherein each of the internal amplifiers amplify each corresponding input signals; and
at least one first N:N multipath switching combiner including N:N multipath switch for switching a connection among the internal amplifiers of the multipath power amplifier.

15. The system of claim 14, further comprising:
at least one antenna for transmitting the combined signal from the combiner.

16. The system of claim 14, further comprising:
at least one second N:N multipath switching combiner for switching an input signal and providing the switched input signals to corresponding internal amplifier of the multipath power amplifier.
